(19) United States
(12) Patent Application Publication
(10) Pub. No.: US 2026/0289050 A1
(43) Pub. Date: Sep. 24, 2026

(54) METHOD FOR ASCERTAINING THE RELIABILITY OF A COMPONENT

(71) Applicant: Robert Bosch GmbH, Stuttgart (DE)

(72) Inventors: Peter Bakucz, Klosterlechfeld (DE); Anna Katharina Stirm, Marbach (DE); Armin Fortwingel, Abstatt (DE)

(21) Appl. No.: 19/568,222

(22) Filed: Mar. 16, 2026

(30) Foreign Application Priority Data
Mar. 18, 2025 (DE) 10 2025 110 321.6

(51) Int. Cl. G06F 30/27

(52) U.S. Cl. CPC G06F 30/27

(57) ABSTRACT

A method for ascertaining the reliability of a component. A computer program, a device, and a storage medium are also described.

### CROSS REFERENCE

The present application claims the benefit under 35 U.S.C. § 119 of Germany Patent Application No. DE 10 2025 110 321.6 filed on Mar. 18, 2025, which is expressly incorporated herein by reference in its entirety.

### FIELD

The present disclosure relates to a method for ascertaining the reliability of a component. The present disclosure furthermore relates to a computer program, a device, and a storage medium for this purpose.

### BACKGROUND INFORMATION

The increased demands on safety and reliability require the provision of suitable methods and tools for modeling hardware problems in vehicles, in particular in the context of autonomous driving. The simulation of thermal effects, for example in high-performance computer motherboards, is a fundamental task of modern automotive electronics. This is true in particular for the development of hardware for self-driving vehicles since thermal stresses expose motherboards to physical effects that may prevent them from reaching their intended service life or fundamentally impair the reliability and safety of self-driving vehicles (e.g., self-driving vehicles fail when overtaking if energy-intensive deep learning algorithms are running at high intensity in parallel).

The motherboard temperature system is based on measurements at geometrically defined points. However, there are points at which deviations can arise up to 1000 times higher than at other points, which can affect the accuracy of the descriptive differential equations system, which in turn can affect the reliability.

Nowadays, dealing with imbalanced datasets in machine learning, in particular in the L4 environment for autonomous driving, plays a key role in data mining. In general, the problem of imbalanced datasets in simulation technology means that one “class” includes far more instances than the other classes. The ratio of minority to majority instances can be 1:100 and 1:1000; overall, the minority class has fewer instances, or data points, than the majority class. In temperature analysis, this can be interpreted as meaning that extremely high temperatures only occur in 1-2 hardware elements, while much lower temperatures occur in much larger proportions. At the same time, the temperature increase of a hardware element is mainly influenced by this maximum thermal load.

Mathematically speaking, the traditional classifiers are interested in the majority class when correcting an imbalanced dataset. Many variables influence the performance of classification; some of these are model structures, parameter tuning and input features, but it is still difficult to find an efficient method that works for all classification problems.

There are many solutions for correcting the problem of imbalanced class distribution, which can be divided into the following categories:

Approaches at the data level that resample the instances to increase the accuracy of predictions. In this case, oversampling, undersampling, and hybrid approaches are addressed. Oversampling approaches, in particular, place synthetic examples in the minority class. With undersampling techniques, original instances are in particular removed from the majority class in order to balance the dataset, while hybrid approaches combine oversampling and undersampling approaches with each other.

Approaches at the algorithm level modify the immediate machine learning models so that they focus on the weak class without adjusting the original data.

The cost-sensitive strategy is a hybrid technique that combines data and algorithm strategies with each other. This strategy provides penalties for training examples and adjusts the learning phase. The machine learning model in this category is interested in instances of minorities by imposing higher penalties on these instances and attempting to reduce the overall penalty in order to increase the accuracy of predictions. Various criteria are examined to achieve acceptable performance where accuracy is insufficient to make a good decision, and high accuracy does not necessarily refer to a perfect machine learning model. In the case of imbalanced data, the traditional classifier will train almost exclusively on the majority instances in the training process, which results in high accuracy.

### SUMMARY

The subject matter of the present disclosure includes a method, a computer program, a device, and a computer-readable storage medium. Features and details of example embodiments are disclosed herein. Features and details that are described in connection with the method according to the present disclosure of course also apply in connection with the computer program according to the present disclosure, the device according to the present disclosure, and the computer-readable storage medium according to the present disclosure, and vice versa in each case, so that mutual reference can also always be made with regard to the disclosure herein.

An object of the present disclosure includes providing a method for ascertaining the reliability of a component. According to an example embodiment, the method comprises the following steps:
providing sensor data, wherein the sensor data result from a detection by at least one sensor and represent measurements on the component, wherein more data points of the sensor data are present in a first value range than in a second value range, i.e., the sensor data are in particular an imbalanced dataset, wherein the second value range is specific for an anomaly in the component, wherein the anomaly is, for example, an impermissibly high temperature in a specific region of the component,
ascertaining a defined number of surrounding data points for each data point of the second value range, for example using the k-nearest neighbors algorithm,
determining a probability value for each data point based on the ascertained surrounding data points that indicate whether a respective data point belongs to the first value range or to the second value range,
determining a measure of entropy, in particular a Shannon entropy, based on the determined probability values, wherein the measure of entropy is determined in particular for the entirety of the sensor data, or for the component,
dividing the data points of the second value range into a defined number of groups based on the determined measure of entropy,
determining a respective fuzzy membership of the data points of the second value range for each group, wherein the fuzzy membership indicates the degree to which a respective data point belongs to the respective group, wherein advantageously, an entropy-based fuzzy membership can be determined by the prior division into groups,
providing an activation function for training a machine learning model based on the specific respective fuzzy memberships, wherein the machine learning model is trained in the context of the training for a classification of data points as data points of the first value range or the second value range.

The method according to the present disclosure can therefore provide an improved activation function with which the training of the machine learning model can be implemented more efficiently and effectively. This advantageously allows a machine learning model to be trained, which can then better ascertain the reliability of the component.

According to an example embodiment, the calculation of the k-nearest neighbors classification is in particular a non-parametric supervised learning method for classification. In doing so, the following steps can be performed: First, the sensor data can be normalized or standardized if different scales are used (e.g., by min-max scaling or Z-standardization).

Subsequently, a value for k can be chosen, i.e., the defined number of surrounding data points. k is therefore, in particular, the number of nearest neighbors that can be used for classification. A small value of k (e.g. 1 or 3) in particular leads to a more sensitive machine learning model, while a large value of k (e.g. 10 or 20) can smooth the machine learning model. A distance to all data points can then be calculated. In this case, various distance metrics can be used such as a Euclidean distance, a Manhattan distance, or a cosine similarity. The calculated distances can now be sorted in ascending order of distance in order to then select the k nearest points. A majority of the k neighbors can then determine the probability of a class affiliation of a respective data point (majority voting) within the framework of the classification.

It is also optionally provided that the method further comprises:
training the machine learning model using the provided activation function, in particular for classifying the data points as data points of the first value range or the second value range,
ascertaining the reliability of the component using the trained machine learning model.

The reliability represents, for example, the service life or the failure rate of the component. In this way, the machine learning model can be trained to classify the data points as belonging to the first or second value range, i.e., for example, whether data points reflect an anomaly such as an unacceptably high temperature in a specific region of the component. The reliability of the component can be ascertained using the trained model, which can provide important insights for maintenance and repair or even for the design of the component.

The method according to the present disclosure makes it possible in particular for the machine learning model to perform a differentiated classification of sensor data based on the provided fuzzy memberships and to more reliably identify anomalies in components, such as excessively high temperatures. The use of the measure of entropy to group data points allows for a hierarchical understanding of the deviations, while fuzzy membership can provide a flexible approach to categorization. This can improve the training of the machine learning model and increase the accuracy of anomaly detection.

Furthermore, within the scope of the present disclosure it is optionally possible for the reliability of the component to be ascertained based on a minimum of weights of the machine learning model, which result in the context of training. In other words, the present disclosure makes it possible to draw conclusions about the reliability of the component by evaluating the weights of the trained machine learning model. The minimum of these weights can serve as an indicator of the quality and accuracy of the classification. This is in particular possible because the minimum weights of the trained machine learning model are proportional to the reliability of the component.

Furthermore, according to an example embodiment, it is advantageous if the ascertainment of the defined number of surrounding data points and the determination of the probability value for several values is performed for the defined number, and the respective entropy is determined for each of the several values, wherein the division of the data points into the defined number of groups (m) is performed based on a maximum (Eₘₐₓ) and minimum (Eₘᵢₙ) entropy determined in the process.

The division can be carried out, for example, based on the following formulas:

$$Low = {E}_{min} + \frac{\text{?}}{m} ( {E}_{max} - {E}_{min} )$$

$$Up = {E}_{min} + \frac{\text{?}}{m} ( {E}_{max} - {E}_{min} )$$

$$\text{?} \text{indicates text missing or illegible when filed}$$

where l∈[1,m].

Preferably, it can be provided within the scope of the present disclosure that the method further comprises:
generating additional data points for the second value range to align a number of data points between the first value range and the second value range.

This can be implemented, for example, using the “random over sampling” (ROS) function, which in particular is a data augmentation technique that can be used in classifying machine learning to balance imbalanced datasets. This can eliminate the underrepresentation of one or more classes. The function duplicates, for example, randomly existing instances, or data points, of the underrepresented class(es) until the ratio between the classes is balanced. The aim of this is, in particular, to improve classification accuracy when one class is dominated by the other.

This has the advantage that the distribution of data points in the training dataset of the machine learning model becomes more balanced. A better balance can lead to improved accuracy and robustness of the trained machine learning model since it processes a greater bandwidth of data points for classifying anomalies in the components.

In another option, it can be provided that the component is a circuit board, in particular a motherboard, of a technical system, in particular a vehicle, wherein the sensor data comprise thermal data, and the at least one sensor is an infrared sensor.

It is therefore possible for the training of the machine learning model to be tailored to the specific thermal properties of the circuit board of a vehicle. The use of an infrared sensor enables precise measurement of thermal data, which can lead to a more accurate classification of anomalies.

It is possible for the method according to the present disclosure to be used in a vehicle. The vehicle can be designed, for example, as a motor vehicle and/or passenger vehicle and/or as an at least partially automated/autonomous vehicle. The vehicle may comprise a vehicle device, for example for providing an autonomous driving function, and/or a driver assistance system. The vehicle device may be designed to at least partially automatically control and/or accelerate and/or brake and/or steer the vehicle.

The machine learning system, in particular in the form of a machine learning model, is in particular trained for classification. Accordingly, the training can at least result in a trained machine learning model that can be used for classification. The data points of the input data can, for example, be pixels of image data, in particular thermal image data, or be based on them in order to perform the classification of the data points on the basis of the pixels. The input data can comprise sensor and/or image data, which at least partially result from detection with a sensor. A classification, preferably image classification, can be provided on the basis of these values. This makes it possible, for example, to identify anomalies such as excessively hot regions in components. The image data can, for example, be images from a radar sensor and/or from an ultrasonic sensor and/or from a LiDAR sensor and/or from a thermal imaging camera. Accordingly, the images can also be designed as radar images and/or ultrasound images and/or thermal images and/or lidar images.

The present disclosure also relates to a computer program, in particular a computer program product, comprising commands which, when the computer program is executed by at least one computer, cause the computer to carry out the method according to the present disclosure. The computer program according to the present disclosure thus delivers the same advantages as have been described in detail with reference to a method according to the present disclosure.

The present disclosure also relates to a data processing device configured to carry out the method according to the present disclosure. For example, at least one computer which executes the computer program according to the present disclosure can be provided as the device. The computer may have at least one processor for executing the computer program. A non-volatile data memory may also be provided, in which the computer program is stored and from which the computer program can be read by the processor for execution.

The present disclosure may also relate to a computer-readable storage medium which comprises the computer program according to the present disclosure and/or commands which, when executed by at least one computer, cause the computer to carry out the method according to the present disclosure. The storage medium is formed, for example, as a data memory such as a hard drive and/or a non-volatile memory and/or a memory card. The storage medium may be integrated into the computer, for example.

Furthermore, the method according to the present disclosure may also be designed as a computer-implemented method. Alternatively or additionally, at least one of the disclosed method steps may be computer-implemented and/or performed automatically.

### BRIEF DESCRIPTION OF THE DRAWINGS

FIG. 1 is a schematic visualization of a method, a device, a storage medium and a computer program according to exemplary embodiments of the present disclosure.

FIG. 2 is a schematic representation of a technical system, a component and a sensor according to exemplary embodiments of the present disclosure.

### DETAILED DESCRIPTION OF EXAMPLE EMBODIMENTS

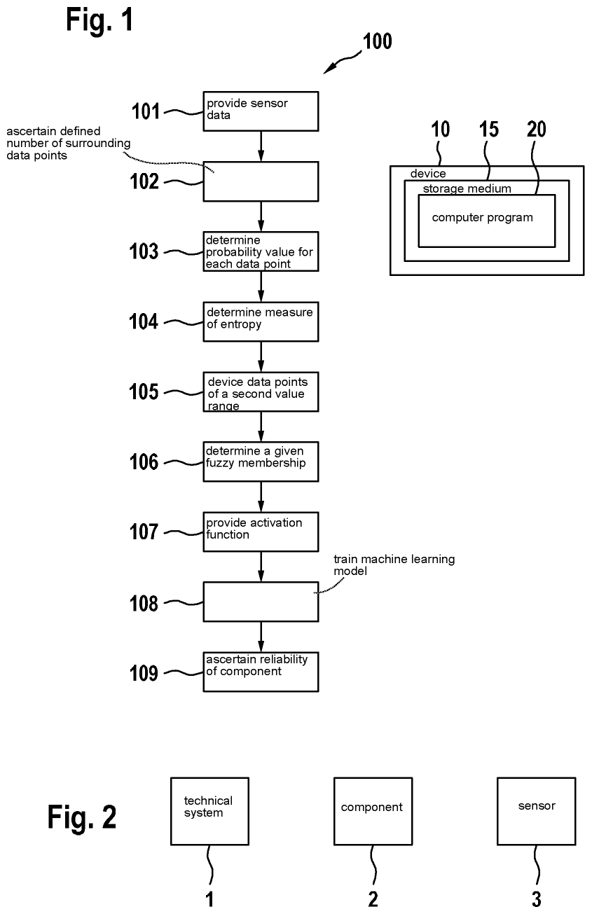

FIG. 1 schematically shows a method 100, a device 10, a storage medium 15, and a computer program 20 according to exemplary embodiments of the present disclosure.

In particular, FIG. 1 shows an exemplary embodiment of a method 100 for ascertaining the reliability of a component. In a first step 101, sensor data are provided, wherein the sensor data result from a detection of at least one sensor 3 and represent measurements on the component 2, wherein more data points of the sensor data exist in a first value range than in a second value range, wherein the second value range is specific for an anomaly in the component 2. In a second step 102, a defined number of surrounding data points is ascertained for each data point of the second value range. In a third step 103, a probability value is determined for each data point based on the ascertained surrounding data points, which indicates whether a respective data point belongs to the first value range or to the second value range. In a fourth step 104, a measure of entropy is determined based on the determined probability values. In a fifth step 105, the data points of the second value range are divided into a defined number of groups based on the determined measure of entropy. In a sixth step 106, a respective fuzzy membership of the data points of the second value range is determined for each group, wherein the fuzzy membership indicates a degree to which a respective data point belongs to the respective group. In a seventh step 107, an activation function is provided for training a machine learning model based on the specific respective fuzzy memberships, wherein the machine learning model is trained in the context of the training for a classification of data points as data points of the first value range or the second value range. In an eighth step 108, the machine learning model is trained using the provided activation function. In a ninth step 109, the reliability of component 2 is ascertained using the trained machine learning model.

FIG. 2 shows a schematic representation of a technical system 1, a component 2 and a sensor 3 according to exemplary embodiments of the present disclosure.

By means of the method according to exemplary embodiments of the present disclosure, the reliability of a component such as an L4 motherboard can be determined based on imbalanced thermal data.

Advantages of the method according to exemplary embodiments of the present disclosure are, for example, the following: The reliability can be determined taking into account the type of real sensor data. When determining the reliability, the lack of redundancy in certain hardware elements is taken into account in particular. The lack of redundancy means, in particular, a much higher thermal load for some elements, while, at the same time, other elements have values much lower than their operating temperature. The number of hardware elements, as well as the geometry and topology of the circuit board, can be easily taken into account and modified. The precise consideration of real sensor data lies, for example, in the (real-time) determination of (Shannon) entropy. Everything can be created locally and without expert knowledge in a way that is easy for designers (not for reliability engineers).

The method is described below according to an exemplary embodiment of the present disclosure. First, with provided sensor data, in particular temperature data, data augmentation can be carried out, for example, by means of the random over sampling (ROS) technique to increase the number of data points with extreme temperature values. These data points are in particular the data points of the second value range according to the present disclosure, which is underrepresented in the sensor data.

Furthermore, the K-nearest neighbors can now be calculated for each data point of the extreme temperature values.

Subsequently, preferably using the formula below, a measure of entropy, in particular a Shannon entropy, is calculated for each minority and majority instance, i.e., in particular for all data points:

$${E}_{i} = - {p}_{+ i} ln ( {p}_{+ i} ) - {p}_{- i} ln ( {p}_{- i} )$$

where p₊ᵢ in particular denotes a probability for positive instances, i.e. data points of the first value range, while p₋ᵢ denotes a probability for negative instances, i.e. data points of the second value range, which depends on the K nearest neighbors of each instance or data point, since the local information for each instance can be provided by its neighbors (kNN). The class safety for each negative instance, i.e., the data points of the second value range, can be determined by the entropy since the measure of entropy measures, in particular, how much information is normally contained in the received message.

Subsequently, the minority instances, i.e., the data points of the second value range, can be determined in m groups with m∈{1, . . . , m} by calculating the lower (Low) and upper (Up) values as follows:

$$Low = {E}_{min} + \frac{\text{?}}{m} ( {E}_{max} - {E}_{min} )$$

$$Up = {E}_{min} + \frac{\text{?}}{m} ( {E}_{max} - {E}_{min} )$$

$$\text{?} \text{indicates text missing or illegible when filed}$$

where Eₘₐₓ is in particular a maximum entropy, Eₘᵢₙ is a minimum entropy, m is a number of subsets and l∈[1,m].

Afterward, a fuzzy membership of the negative instances, i.e., the data points of the second value range, in each group can be determined as follows:

$${FM}_{l} , = 1. - ( β * ( I - 1 ) ) , I = 1 , 2 \text{?} , m$$

$$\text{?} \text{indicates text missing or illegible when filed}$$

where FMₗ is in particular the fuzzy membership and β is in particular a fuzzy membership parameter, which is defined, for example, as follows:

$$β ∈ ( 0 , \frac{1}{( m - 1 )} ]$$

The entropy-based fuzzy membership can be determined as follows:

$${W}_{i} = \{ \begin{matrix}1. , & if {y}_{i} = + 1 \\ F \text{?} , & if {y}_{i} = - 1 \&\& {x}_{i} ∈ Su \text{?}\end{matrix}$$

$$\text{?} \text{indicates text missing or illegible when filed}$$

where in particular Wᵢ represents the entropy-based fuzzy membership for instances or data points, and yᵢ is in particular an actual class.

Subsequently, a machine learning model can be used which uses backpropagation for the m groups to classify minority and majority classes, wherein the activation function in the context of training neurons of the machine learning model is based in particular on the fuzzy membership function based on the measure of entropy.

Finally, a minimum of the learned weights of the trained machine learning model can ultimately reflect the reliability of the component, or the L4 motherboard, based on the imbalanced thermal data.

The above description describes the present disclosure exclusively in the context of examples and example embodiments. Of course, individual features of the embodiments, provided they are technically feasible, can be freely combined with one another without departing from the scope of the present disclosure.

What is claimed is:

1. A method for ascertaining a reliability of a component, the method comprising the following steps:
providing sensor data, wherein the sensor data result from a detection of at least one sensor and represent measurements on the component, wherein more data points of the sensor data exist in a first value range than in a second value range, wherein the second value range is specific for an anomaly in the component;
ascertaining a defined number of surrounding data points for each data point of the second value range;
determining a probability value for each respective data point based on the ascertained surrounding data points, that indicates whether the respective data point belongs to the first value range or to the second value range;
determining a measure of entropy based on the determined probability values;
dividing the data points of the second value range into a defined number of groups based on the determined measure of entropy;
determining a respective fuzzy membership of each respective data point of the data points of the second value range for each respective group of the groups, wherein each respective fuzzy membership indicates a degree to which the respective data point belongs to the respective group;
providing an activation function for training a machine learning model based on the respective fuzzy memberships, wherein the machine learning model is trained in a context of training for a classification of data points as data points of the first value range or the second value range;
training the machine learning model using the provided activation function; and
ascertaining the reliability of the component using the trained machine learning model.

2. The method according to claim 1, wherein the reliability of the component is ascertained based on a minimum of weights of the machine learning model which result in the context of training.

3. The method according to claim 1, wherein the reliability represents a service life or a failure rate of the component.

4. The method according to claim 1, wherein the ascertainment of the defined number of surrounding data points and the determination of the probability value for several values is performed for the defined number, and the respective entropy is determined for each of the several values, wherein the division of the data points into the defined number of groups is performed based on a determined maximum and minimum entropy.

5. The method according to claim 1, further comprising:
generating additional data points for the second value range to align a number of data points between the first value range and the second value range.

6. The method according to claim 1, wherein the component is a motherboard of a vehicle, wherein the sensor data include thermal data, and the at least one sensor is an infrared sensor.

7. A device for processing data, the device configured for ascertaining a reliability of a component, the device being configured to perform the following steps comprising:
providing sensor data, wherein the sensor data result from a detection of at least one sensor and represent measurements on the component, wherein more data points of the sensor data exist in a first value range than in a second value range, wherein the second value range is specific for an anomaly in the component;
ascertaining a defined number of surrounding data points for each data point of the second value range;
determining a probability value for each respective data point based on the ascertained surrounding data points, that indicates whether the respective data point belongs to the first value range or to the second value range;
determining a measure of entropy based on the determined probability values;
dividing the data points of the second value range into a defined number of groups based on the determined measure of entropy;
determining a respective fuzzy membership of each respective data point of the data points of the second value range for each respective group of the groups, wherein each respective fuzzy membership indicates a degree to which the respective data point belongs to the respective group;
providing an activation function for training a machine learning model based on the respective fuzzy memberships, wherein the machine learning model is trained in a context of training for a classification of data points as data points of the first value range or the second value range;
training the machine learning model using the provided activation function; and
ascertaining the reliability of the component using the trained machine learning model.

8. A non-transitory computer-readable storage medium on which are stored commands for ascertaining a reliability of a component, the commands, when executed by at least one computer, causing the at least one computer to perform the following steps comprising:
providing sensor data, wherein the sensor data result from a detection of at least one sensor and represent measurements on the component, wherein more data points of the sensor data exist in a first value range than in a second value range, wherein the second value range is specific for an anomaly in the component;
ascertaining a defined number of surrounding data points for each data point of the second value range;
determining a probability value for each respective data point based on the ascertained surrounding data points, that indicates whether the respective data point belongs to the first value range or to the second value range;
determining a measure of entropy based on the determined probability values;
dividing the data points of the second value range into a defined number of groups based on the determined measure of entropy;
determining a respective fuzzy membership of each respective data point of the data points of the second value range for each respective group of the groups, wherein each respective fuzzy membership indicates a degree to which the respective data point belongs to the respective group;
providing an activation function for training a machine learning model based on the respective fuzzy memberships, wherein the machine learning model is trained in a context of training for a classification of data points as data points of the first value range or the second value range;
training the machine learning model using the provided activation function; and
ascertaining the reliability of the component using the trained machine learning model.
